(19) United States
(12) Patent Application Publication
(10) Pub. No.: US 2021/0066593 A1
(43) Pub. Date: Mar. 4, 2021

(54) DOPANT ACTIVATION ANNEAL FOR CORRELATED ELECTRON DEVICE

(71) Applicant: Cerfe Labs, Inc., Austin, TX (US)

(72) Inventors: Ming He, San Jose, CA (US); Paul Raymond Besser, Sunnyvale, CA (US); Jolanta Bozena Celinska, Colorado Springs, CO (US); Carlos Alberto Paz de Araujo, Colorado Springs, CO (US)

(21) Appl. No.: 16/554,385

(22) Filed: Aug. 28, 2019

(51) Int. Cl. H01L 45/00; H01L 21/67

(52) U.S. Cl. CPC H01L 45/1641; H01L 45/1608; H01L 45/146; H01L 45/1233; H01L 21/67115; H01L 45/10; H01L 45/1675

(57) ABSTRACT

Subject matter disclosed herein may relate to fabrication of a correlated electron material (CEM) device. In particular embodiments, formation of a CEM device may include application of rapid thermal annealing to doped layers of a metal oxide.

### BACKGROUND

### Field

This disclosure relates to devices formed from correlated electron material (CEM), and may relate, more particularly, to approaches for fabricating CEM devices, such as may be used in switches, memory circuits, and so forth, which may exhibit desirable impedance switching characteristics.

### Information

Integrated circuit devices, such as electronic switching devices, for example, may be found in numerous types of electronic devices. For example, memory and/or logic devices may incorporate electronic switches suitable for use in computers, digital cameras, smart phones, computing devices, wearable electronic devices, and so forth. Factors that may relate to electronic switching devices, which may be of interest to a designer in considering whether an electronic switching device is suitable for particular applications, may include physical size, storage density, operating voltages, impedance ranges, switching speed, and/or power consumption, for example. Other factors may include, for example, cost and/or ease of manufacture, scalability, and/or reliability.

However, conventional fabrication techniques, which may be suitable for certain types of memory and/or logic devices, may not be suited for use in fabricating correlated electron material devices that exhibit desired switching capabilities and/or impedance properties.

### BRIEF DESCRIPTION OF THE DRAWINGS

Claimed subject matter is particularly pointed out and distinctly claimed in the concluding portion of the specification. However, both as to organization and/or method of operation, together with objects, features, and/or advantages thereof, it may best be understood by reference to the following detailed description if read with the accompanying drawings in which:

FIG. 1A is an illustration of an embodiment of a current density versus voltage profile of a device formed from a correlated electron material;

FIG. 1B is an illustration of an embodiment of a switching device comprising a correlated electron material and a schematic diagram of an equivalent circuit of a correlated electron material switch;

FIGS. 2A-2G illustrate embodiments of sub-processes, which may be utilized to form a correlated electron material device;

FIGS. 3A and 3B are plots illustrating a profile of a surface temperature of a device undergoing rapid thermal annealing (RTA) according to an embodiment;

FIG. 3C is a schematic diagram of an apparatus to implement RTA according to an embodiment; and

FIG. 4 is a flow diagram illustrating a process of fabricating and/or constructing a CEM switching device according to embodiments.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### DETAILED DESCRIPTION

References throughout this specification to one implementation, an implementation, one embodiment, an embodiment, and/or the like indicates that a particular feature, structure, characteristic, and/or the like described in relation to a particular implementation and/or embodiment is included in at least one implementation and/or embodiment of claimed subject matter. Thus, appearances of such phrases, for example, in various places throughout this specification are not necessarily intended to refer to the same implementation and/or embodiment or to any one particular implementation and/or embodiment. Furthermore, it is to be understood that particular features, structures, characteristics, and/or the like described are capable of being combined in various ways in one or more implementations and/or embodiments and, therefore, are within intended claim scope. In general, of course, as has been the case for the specification of a patent application, these and other issues have a potential to vary in a particular context of usage. In other words, throughout the disclosure, particular context of description and/or usage provides helpful guidance regarding reasonable inferences to be drawn; however, likewise, “in this context” in general without further qualification refers to the context of the present disclosure.

According to an embodiment, correlated electron material (CEM) devices may comprise one or more layers of CEM formed between metallic electrodes by, for example, deposition of one or more layers of a metal oxide combined with a dopant. Following deposition of one or more layers of a metal oxide combined with a dopant, one or more periods of rapid thermal annealing (RTA) may be applied to the layers to activate the dopant in the metal oxide to impart a p-type property to the deposited layers of material. In an implementation, application of RTA may enable one or more improvements of an annealing process in the formation of CEM layers in a device including, for example, improved control of grain size, stabilize CEM layers and control of chemistry in CEM layers.

Particular aspects of the present disclosure describe methods and/or processes for preparing and/or fabricating correlated electron materials (CEMs) films to form, for example, a correlated electron switch, such as may be utilized to form a correlated electron random access memory (CERAM), and/or logic devices, for example. Correlated electron materials, which may be utilized in the construction of CERAM devices and CEM switches, for example, may also comprise a wide range of other electronic circuit types, such as, for example, memory controllers, memory arrays, filter circuits, data converters, optical instruments, phase locked loop circuits, microwave and millimeter wave transceivers, and so forth, although claimed subject matter is not limited in scope in these respects.

In this context, a CEM switch, for example, may exhibit a substantially rapid conductive-state-to-insulative-state transition, which may be enabled, at least in part, by electron correlations, which modify electrical properties of the material, rather than solid-state structural phase changes, such as in response to a change from a crystalline to an amorphous state, for example. Such solid-state structural phase changes, such as from crystalline to amorphous states, for example, may bring about formation of conductive filaments in certain resistive RAM devices. In one aspect, a substantially rapid conductor-to-insulator transition in a CEM device may occur responsive to a quantum mechanical phenomenon that takes place within a bulk of a material making up such an CEM device, in contrast to melting/solidification and/or localized filament formation, for example, in phase change and certain resistive RAM devices. Such quantum mechanical transitions between relatively conductive and relatively insulative states, and/or between a first impedance state and a second, dissimilar impedance state, for example, in a CEM device may be understood in any one of several aspects. As used herein, the terms “relatively conductive state,” “relatively lower impedance state,” and/or “metal state” may be interchangeable, and/or may, at times, be referred to as a “relatively conductive and/or lower-impedance state.” Likewise, the terms “relatively insulative state” and “relatively higher impedance state” may be used interchangeably herein, and/or may, at times, be referred to as a “relatively insulative and/or higher impedance state.” Further, in a relatively insulative and/or higher-impedance state, a CEM may be characterized by a range of impedances, and in a relatively conductive and/or lower-impedance state, a CEM may be characterized by a second range of impedances.

In an aspect, a quantum mechanical transition of a CEM between a relatively insulative and/or higher impedance state and a relatively conductive and/or lower impedance state, wherein the relatively conductive and/or lower impedance state is substantially dissimilar from the insulative and/or higher impedance state, may be understood in terms of a Mott transition. In accordance with a Mott transition, a material may switch between a relatively insulative and/or higher impedance state and a relatively conductive and/or lower impedance state if a Mott transition condition occurs. Mott criteria may be defined by (n_{c})^{1/3} a ≈ 0.26, wherein n_{c} denotes a concentration of electrons, and wherein “a” denotes the Bohr radius. If a threshold charge density is achieved, such that Mott criteria is met, a Mott transition may be believed to occur. Responsive to occurrence of a Mott transition, a state of a CEM device may change from a relatively higher resistance and/or higher capacitance state (e.g., a higher-impedance and/or insulative state) to a relatively lower resistance and/or lower capacitance state (e.g., a lower-impedance and/or conductive state) that is substantially dissimilar from the higher resistance and/or higher capacitance state.

In another aspect, a Mott transition may be controlled by a localization of electrons. If carriers, such as electrons, for example, are localized, a strong coulomb interaction between carriers may split bands of the CEM (e.g., split conductive and valence bands) to bring about a relatively insulative (relatively higher impedance) state. If electrons are no longer localized, a weak coulomb interaction may dominate, which may give rise to a removal of band splitting.

Further, in an embodiment, switching from a relatively insulative and/or higher impedance state to a substantially dissimilar and relatively conductive and/or lower impedance state may enable a change in capacitance in addition to a change in resistance. For example, a CEM device may exhibit a variable resistance together with a property of a variable capacitance. In other words, impedance characteristics of a CEM device may include both resistive and capacitive components. For example, in a metallic state, a CEM device may comprise a relatively low electric field that may approach zero, and thus may exhibit a substantially low capacitance, which may likewise approach zero.

Similarly, in a relatively insulative and/or higher impedance state, which may be brought about by a higher density of bound or correlated electrons, an external electric field may be capable of penetrating a CEM and, therefore, such a CEM may exhibit higher capacitance based, at least in part, on additional charges stored within the CEM. Thus, for example, a transition from a relatively insulative and/or higher impedance state to a substantially dissimilar and relatively conductive and/or lower impedance state in a CEM device may result in changes in both resistance and capacitance, at least in particular embodiments. Such a transition may bring about additional measurable phenomena, and claimed subject matter is not limited in this respect.

In an embodiment, a device formed from a CEM may exhibit switching of impedance states responsive to a Mott-transition occurring in a majority of bulk volume of CEM forming a CEM-based device. In an embodiment, a CEM may form a “bulk switch.” As used herein, the term “bulk switch” refers to at least a substantial volume of a CEM switching a device's impedance state, such as between a low impedance and/or conductive state and a high impedance and/or insulative responsive to a Mott-transition. For example, in an embodiment, substantially all CEM of a device may switch between a relatively insulative and/or higher impedance state and a relatively conductive and/or lower impedance state (e.g., a “metal” or “metallic state”) responsive to a Mott transition, or from a relatively conductive and/or lower impedance state to a relatively insulative and/or higher impedance state responsive to a reverse Mott transition.

In implementations, a CEM may comprise one or more “d block” elements or compounds of “d block” elements, which correspond to transition metals and/or transition metal oxides (TMOs). CEM devices may also be implemented utilizing one or more “f block” elements or compounds of “f block” elements. A CEM may comprise one or more rare earth elements, oxides of rare earth elements, oxides comprising one or more rare earth transition metals, perovskites, yttrium, and/or ytterbium, or any other compounds comprising metals from the lanthanide or actinide series of the periodic table of the elements, for example, and claimed subject matter is not limited in scope in this respect. A CEM may additionally comprise a dopant, such as a carbon-containing dopant and/or a nitrogen-containing dopant, wherein an atomic concentration of a resulting ligand (e.g., of carbon or nitrogen) in a CEM may be controlled in part to be a particular predefined atomic concentration (e.g., between about 1.0 parts per million (ppm) to about 20.0%).

In this context, a “ligand” as referred to herein means an ion or molecule attached to a metal atom by coordinate bonding. In the case of a metal oxide or metal chalcogenide, for example, such a ligand may comprise ions of oxygen bonding to a metal ion. In a process to form a CEM (e.g., to enhance switching properties of a metal oxide), a dopant may be applied to a host material (e.g., a metal oxide). In this context, a “dopant” or “doping agent” as referred to herein means an impurity that is introduced into a host material to alter one or more original electrical and/or optical properties of the host material. In one embodiment of a metal oxide host material, oxygen may serve as an “intrinsic ligands.” In a particular implementation of a process to form a bulk material having desired properties (e.g., a CEM), application of a dopant may introduce an “extrinsic ligand” such as carbon, nitrogen and/or CO capable of binding with molecules of the host material to substitute for intrinsic ligands if vacancies occur in molecules of the host material. In this context, an extrinsic ligand, as a ligand supplied by an applied dopant, may comprise a “substitutional ligand” that binds to a vacancy of a metal ion.

As the term is used herein, a “d block” element means an element comprising scandium (Sc), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), hafnium (Hf), tantalum (Ta), tungsten (W), rhenium (Re), osmium (Os), iridium (Ir), platinum (Pt), gold (Au), mercury (Hg), rutherfordium (Rf), dubnium (Db), seaborgium (Sg), bohrium (Bh), hassium (Hs), meitnerium (Mt), darmstadtium (Ds), roentgenium (Rg) or copernicium (Cn), or any combination thereof. A CEM formed from or comprising an “f block” element of the periodic table of elements means a CEM comprising a metal or metal oxide, wherein the metal is from the F block of the periodic table of elements, which may include lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), actinium (Ac), thorium (Th), protactinium (Pa), uranium (U), neptunium (Np), plutonium (Pu), americium (Am), berkelium (Bk), californium (Cf), einsteinium (Es), fermium (Fm), mendelevium (Md), nobelium (No) or lawrencium (Lr), or any combination thereof.

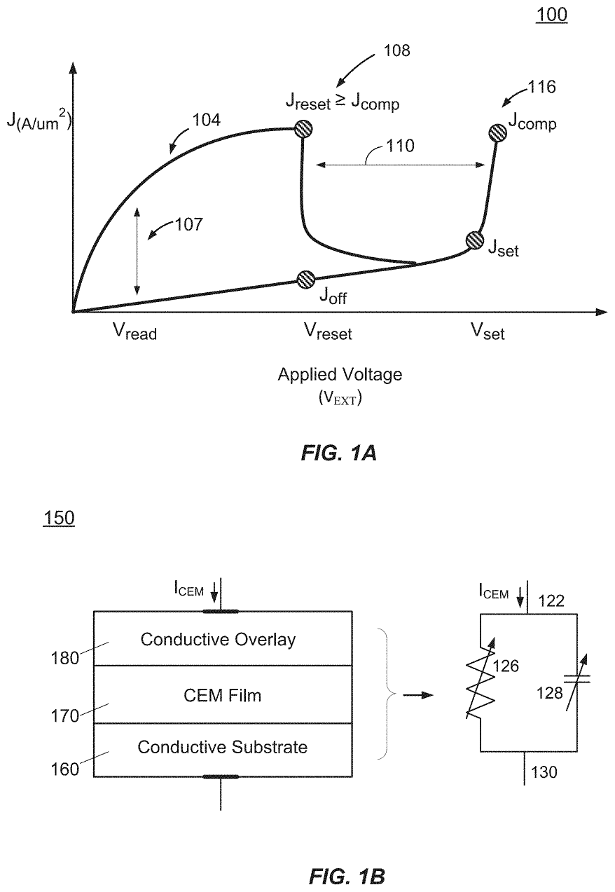

FIG. 1A is an illustration of an embodiment 100 of a current density (J) versus an applied voltage (V_{EXT}) for a device formed from a CEM. At least partially responsive to a voltage applied to terminals of a CEM device, for example, during a “write operation,” such a CEM device may be placed into a relatively low-impedance and/or conductive state or a relatively high-impedance and/or insulative state. For example, application of a voltage Vₛₑₜ and a current density Jₛₑₜ may enable a transition of a CEM device to a relatively low-impedance and/or conductive state. Conversely, application of a voltage Vᵣₑₛₑₜ and a current density Jᵣₑₛₑₜ may enable a transition of a CEM device to a relatively high-impedance and/or insulative state. As shown in FIG. 1A, reference designator 110 may illustrate a voltage range that may separate Vₛₑₜ from Vᵣₑₛₑₜ. Following placement of a CEM device into a high-impedance state and/or insulative or into a low-impedance and/or conductive state, a particular state of such a CEM device may be detectable by application of a voltage V_{read} (e.g., during a read operation) and detection of a current and/or current density at terminals of the CEM device (e.g., utilizing read window 107).

According to an embodiment, a CEM device characterized in FIG. 1A may comprise any one of several metal oxides, such as, for example, perovskites, Mott insulators, charge exchange insulators, and Anderson disorder insulators, as well as any one of several compounds and/or materials comprising a d block and/or f block element. In one aspect, a CEM device according to FIG. 1A may comprise other types of TMO switching materials, though it should be understood that these are exemplary only and are not intended to limit claimed subject matter. Nickel oxide (NiO) is disclosed as one particular TMO material. NiO materials discussed herein may be doped with substitutional ligands, such as carbon-containing materials (e.g., carbon, carbon monoxide carbonyl (CO)₄), or nitrogen-containing materials, such as ammonia (NH₃), for example, which may establish and/or stabilize material properties and/or enable a p-type operation in which a CEM may be more conductive while placed into a low-impedance and/or conductive state. Thus, in another particular example, NiO doped with substitutional ligands may be expressed as NiO:Lₓ, where Lₓ may indicate a ligand element and/or compound and x may indicate a number of units of the ligand for one unit of NiO. A value of x may be determined for a specific ligand and/or a specific combination of ligands with NiO or with another transition metal compound by balancing valences. Other dopant ligands, which may enable or increase conductivity in a metal oxide in addition to carbonyl may include, for example: nitrosyl (NO), an isocyanide (RNC wherein R is H, C₁-C₆ alkyl or C₆-C₁₀ aryl), a phosphine (R₃P wherein R is C₁-C₆ alkyl or C₆-C₁₀ aryl) for example, triphenylphosphine (PPh₃), an alkyne (e.g., ethyne) or phenanthroline (C₁₂H₈N₂), bipyridine (C₁₀H₈N₂), ethylenediamine (C₂H₄(NH₂)₂), acetonitrile (CH₃CN), fluoride (F), chloride (Cl), bromide (Br), cyanide (CN), sulfur (S), carbon (C), and others.

In this context, a “p-type” doped CEM as referred to herein means a first type of CEM comprising a particular molecular dopant that exhibits increased electrical conductivity, relative to an undoped CEM, while such CEM is operated in a relatively low-impedance and/or conductive state. Introduction of a substitutional ligand, such as CO and/or NH₃ by way of application of a dopant, may operate to enhance a p-type nature of a NiO-based CEM, for example. Accordingly, an attribute of p-type operation of a CEM may include, at least in particular embodiments, an ability to tailor and/or customize electrical conductivity of a CEM at least in part by controlling an atomic concentration of a p-type dopant in a CEM. In particular embodiments, an increased atomic concentration of a p-type ligand may enable increased electrical conductivity of a CEM, although claimed subject matter is not limited in this respect. In particular embodiments, changes in atomic concentration and/or atomic percentage of p-type ligand in a CEM may be observed in characteristics of region 104 of FIG. 1A, as described herein, wherein an increase in p-type ligand may bring about a steeper (e.g., more positive) slope of region 104 to indicate higher conductivity.

In another embodiment, a CEM device represented by a current density versus voltage profile of FIG. 1A, may comprise other TMO materials, such as carbon-containing ligands or nitrogen-containing ligands, though it should be understood that these are exemplary only and are not intended to limit claimed subject matter. NiO, for example, may be doped with substitutional carbon- and/or nitrogen-containing ligands, which may stabilize switching properties in a manner similar to stabilization switching properties responsive to use of a carbon-containing dopant species (e.g., carbonyl). In particular, NiO materials disclosed herein may include nitrogen-containing molecules of the form CₓH_{y}N_{z} (wherein x≥0, y≥0, z≥0, and wherein at least x, y, or z comprise values>0) such as ammonia (NH₃), cyano (CN⁻), azide ion (N₃⁻) ethylene diamine (C₂H₈N₂), phen(1,10-phenanthroline) (C₁₂H₈N₂), 2,2′bipyridine (C₁₀,H₈N₂), ethylenediamine ((C₂H₄(NH₂)₂), pyridine (C₅H₅N), acetonitrile (CH₃CN), and cyanosulfanides such as thiocyanate (NCS⁻), for example. NiO switching materials disclosed herein may include members of an oxynitride family (NₓO_{y}, wherein x and y comprise whole numbers, and wherein x≥0 and y≥0 and at least x or y comprise values>0), which may include, for example, nitric oxide (NO), nitrous oxide (N₂O), nitrogen dioxide (NO₂), or precursors with an NO₃⁻ ligand.

In accordance with FIG. 1A, if sufficient bias voltage is applied (e.g., exceeding a band-splitting potential) and an aforementioned Mott condition is satisfied (e.g., injected electron holes are of a population comparable to a population of electrons in a switching region, for example), a CEM device may switch between a relatively low-impedance and/or conductive state and a relatively high-impedance and/or insulative state, for example, responsive to a Mott transition. This may correspond to point 108 of the voltage versus current density profile of FIG. 1A. At, or suitably near this point, electrons may no longer be screened and become localized near a metal ion. This correlation may result in a strong electron-to-electron interaction potential, which may operate to split bands to form a relatively high-impedance and/or insulative material. If a CEM device comprises a relatively high-impedance and/or insulative state, current may be generated by transportation of electron holes. Consequently, if a threshold voltage is applied across terminals of a CEM device, electrons may be injected into a metal-insulator-metal (MIM) diode over a potential barrier of such an MIM device. In certain embodiments, injection of a threshold current of electrons, at a threshold potential applied across terminals of a CEM device, may perform a “set” operation, which may place such a CEM device into a low-impedance and/or conductive state. In a low-impedance and/or conductive state, an increase in electrons may screen incoming electrons and remove a localization of electrons, which may operate to collapse the band-splitting potential, thereby giving rise to a low-impedance and/or conductive state.

In accordance with particular embodiments, current and/or current density in a CEM device may be controlled by an externally applied “compliance” condition, which may be determined at least partially on the basis of an applied external current, which may be limited during a write operation, for example, to place the CEM device into a relatively low-impedance and/or conductive state. This externally applied compliance current may, in some embodiments, also determine a condition of a current density in CEM for a subsequent reset operation to place the CEM device into a relatively high-impedance and/or insulative state. As shown in the particular implementation of FIG. 1A, a voltage Vₛₑₜ may be applied during a write operation to give rise to a current density J_{comp}, such as at point 116, to place the CEM device into a relatively low-impedance and/or conductive state, which may determine a compliance condition for placing the CEM device into a relatively high-impedance and/or insulative state in a subsequent write operation. As shown in FIG. 1A, a CEM device may be subsequently placed into a high-impedance and/or insulative state by application of an externally applied voltage (Vᵣₑₛₑₜ), which may give rise to a current density Jᵣₑₛₑₜ≥J_{comp} at a voltage referenced by 108 in FIG. 1A.

In embodiments, a compliance condition may determine a number of electrons in a CEM device that may be “captured” by holes for a Mott transition. In other words, a current and/or current density applied in a write operation to place a CEM device into a relatively low-impedance and/or conductive memory state may determine a number of holes to be injected to the CEM device for subsequently transitioning the CEM device to a relatively high-impedance and/or insulative state.

As pointed out above, a reset condition may occur responsive to a Mott transition at point 108. As pointed out above, such a Mott transition may give rise to a condition in a CEM device in which a concentration of electrons n approximately equals, or becomes at least comparable to, a concentration of electron holes p. This condition may be modeled according to expression (1) as follows:

$${λ}_{TF} {n}^{\frac{1}{3}} = C ∼ 0.26 \\ n = {( \frac{C}{{λ}_{TF}} )}^{3} \qquad ( 1 )$$

In expression (1), λ_{TF} corresponds to a Thomas Fermi screening length, and C is a constant.

According to an embodiment, a current and/or current density in region 104 of the voltage versus current density profile shown in FIG. 1A may occur responsive to injection of holes from a voltage signal applied across terminals of a CEM device, which may correspond to P-type operation of the CEM device. Here, injection of holes may meet a Mott transition criterion for a low-impedance and/or conductive state to high-impedance and/or insulative state transition at current IMI as a threshold voltage V_{MI} is applied across terminals of a CEM device. This may be modeled according to expression (2) as follows:

$${I}_{MI} ( {V}_{MI} ) = \frac{dQ ( {V}_{MI} )}{d t} \approx \frac{Q ( {V}_{MI} )}{t} \\ Q ( {V}_{MI} ) = qn ( {V}_{MI} ) \qquad ( 2 )$$

In expression (2), Q(V_{MI}) corresponds to a charged injected (holes or electrons) and may, at least in part, be a function of an applied voltage. Injection of electrons and/or holes to enable a Mott transition may occur between bands and responsive to threshold voltage V_{MI}, and threshold current I_{MI}. By equating electron concentration n with a charge concentration to bring about a Mott transition by holes injected by I_{MI} in expression (2) according to expression (1), a dependency of such a threshold voltage
V_{MI} on Thomas Fermi screening length λ_{TF} may be modeled according to expression (3), as follows:

$${I}_{MI} ( {V}_{MI} ) = \frac{Q ( {V}_{MI} )}{t} = \frac{qn ( {V}_{MI} )}{t} = \frac{q}{t} {( \frac{C}{{λ}_{TF}} )}^{3} \\ {J}_{reset} ( {V}_{MI} ) = {J}_{MI} ( {V}_{MI} ) = \frac{{I}_{MI} ( {V}_{MI} )}{{A}_{CEM}} = \frac{q}{{A}_{CEM} t} {( \frac{C}{{λ}_{TF} ( {V}_{MI} )} )}^{3} \qquad ( 3 )$$

In expression (3), A_{CEM} is a cross-sectional area of a CEM device; and expression (3) may represent a current density through the CEM device to be applied to the CEM device at a threshold voltage V_{MI}, which may place the CEM device into a relatively high-impedance and/or insulative state.

According to an embodiment, a CEM device, which may be utilized to form a CEM switch, a CERAM memory device, and/or a variety of other electronic devices comprising one or more correlated electron materials, may be placed into a relatively low-impedance and/or conductive memory state, such as by transitioning from a relatively high-impedance and/or insulative state, for example, via injection of a sufficient quantity of electrons to satisfy a Mott transition criteria. In transitioning a CEM device to a relatively low-impedance and/or conductive state, if enough electrons are injected and a potential across terminals of such a CEM device overcomes a threshold switching potential (e.g., Vₛₑₜ), injected electrons may begin to screen. As previously mentioned, screening may operate to unlocalize double-occupied electrons to collapse band-splitting potential, thereby bringing about a relatively low-impedance and/or conductive state.

In particular embodiments, changes in impedance states of a CEM device may be brought about by “back-donation” of electrons of compounds comprising NiₓO_{y} (wherein the subscripts “x” and “y” comprise whole numbers). As the term is used herein, “back-donation” refers to a supplying of one or more electrons (e.g., increased electron density) to a metal, metal oxide, or any combination thereof (e.g., to an atomic orbital of a metal), by an adjacent molecule of a lattice structure, such as a ligand and/or dopant. Back-donation also refers to a reversible donation of electrons (e.g., an increase electron density) from a metal atom to an unoccupied π-antibonding orbital on a ligand and/or dopant. Back-donation may permit a metal, metal compound or metal oxide, or a combination thereof, to maintain an ionization state that is favorable to electrical conduction under an influence of an applied voltage. In certain embodiments, back-donation in a CEM, for example, may occur responsive to application of carbon-containing dopants, such as carbonyl (CO)₄, or a nitrogen-containing dopant species, such as ammonia (NH₃), ethylene diamine (C₂H₈N₂), or members of an oxynitride family (NₓO_{y}), for example, which may permit a CEM to exhibit a property in which electrons are controllably, and reversibly, “donated” to a conduction band of a metal or metal oxide, such as nickel or nickel oxide, for example, during operation of a device or circuit comprising a CEM. Back donation may be reversed, for example, in a nickel oxide material (e.g., NiO:CO or NiO:NH₃), thereby permitting such a nickel oxide material to switch to exhibiting a substantially dissimilar impedance property, such as a high-impedance and/or insulative property, during device operation.

Thus, in this context, an electron back-donating material refers to a material that exhibits an impedance switching property, such as switching from a first impedance state to a substantially dissimilar second impedance state (e.g., from a relatively low impedance state to a relatively high impedance state, or vice versa) responsive, at least in part, to an applied voltage to control donation of electrons, and reversal of the electron donation, to and from a conduction band of a CEM.

In some embodiments, by way of back-donation, a CEM switch comprising a transition metal (e.g., in a transition metal compound and/or a transition metal oxide), may exhibit low-impedance and/or conductive properties if such a transition metal, such as nickel, for example, is placed into an oxidation state of 2+ (e.g., Ni²⁺ in a material, such as NiO:CO or NiO:NH₃). Conversely, electron back-donation in a CEM comprising a transition metal, such as nickel, may be reversed by placing such a transition metal into an oxidation state of 1+ or 3+. Accordingly, during operation of a nickel-based CEM device, back-donation may result in “disproportionation,” which may comprise substantially simultaneous oxidation and reduction reactions, substantially in accordance with expression (4), below:

2Ni²⁺→Ni¹⁺+Ni³⁺ (4)

Such disproportionation, in the specific example of expression (4), refers to formation of nickel ions as Ni¹⁺+Ni³⁺, which may bring about, for example, a relatively high-impedance and/or insulative state during operation of a CEM device. In an embodiment, application of a dopant such as a carbon-containing ligand, carbonyl (CO) and/or a nitrogen-containing ligand, such as an ammonia molecule (NH₃), may permit sharing of electrons during operation of a nickel-based CEM device so as to give rise to the disproportionation reaction of expression (4), and its reversal, substantially in accordance with expression (5), below:

Ni¹⁺+Ni³⁺→2Ni²⁺ (5)

As previously mentioned, reversal of a disproportionation reaction, as shown in expression (5), may permit a nickel-based CEM to return to a relatively low-impedance and/or conductive state.

In embodiments, depending on a molecular concentration of NiO:CO or NiO:NH₃, for example, which may vary from values approximately in the range of an atomic percentage of about 0.1% to about 20.0%, magnitudes of Vᵣₑₛₑₜ and Vₛₑₜ (|Vₛₑₜ| and |Vᵣₑₛₑₜ|, respectively), as shown in FIG. 1A, may vary approximately in the range of about 0.1 V to about 10.0 V subject to the condition that |Vₛₑₜ|≥|Vᵣₑₛₑₜ|. For example, in one possible embodiment, |Vᵣₑₛₑₜ| may occur at a voltage approximately in a range of about 0.1 V to about 1.0 V, and |Vₛₑₜ| may occur at a voltage approximately in a range of about 1.0 V to about 2.0 V, for example. It should be noted, however, that variations in magnitudes of Vₛₑₜ and Vᵣₑₛₑₜ may occur based, at least in part, on a variety of factors, such as atomic concentration of an electron back-donating material, such as NiO:CO or NiO:NH₃ and other materials present in a CEM device, as well as other process variations, and claimed subject matter is not limited in this respect.

FIG. 1B is an illustration of an embodiment 150 of a switching device comprising a CEM and a schematic diagram of an equivalent circuit of a CEM switch. As previously mentioned, a correlated electron device, such as a CEM switch, a CERAM array, or other type of device utilizing one or more CEMs may comprise a variable or complex impedance device that may exhibit characteristics of both variable resistance and variable capacitance. In other words, impedance characteristics for a CEM variable impedance device, such as a device comprising conductive substrate 160, CEM film 170, and conductive overlay 180, may depend at least in part on resistance and capacitance characteristics of such a device measured across device terminals 122 and 130. In an embodiment, an equivalent circuit for a variable impedance device may comprise a variable resistor, such as variable resistor 126, in parallel with a variable capacitor, such as variable capacitor 128. Of course, although variable resistor 126 and variable capacitor 128 are depicted in FIG. 1B as comprising discrete components, a variable impedance device, such as a device of embodiment 150, may comprise a substantially homogenous CEM film and/or bulk CEM film, and claimed subject matter is not limited in this respect.

Table 1 below depicts characteristics of an example variable impedance device, such as a device of embodiment 150.

TABLE 1
Correlated Electron Switch Truth Table

| Resistance | Capacitance | Impedance |
|---|---|---|
| R_{high}(V_{applied}) | C_{high}(V_{applied}) | Z_{high}(V_{applied}) |
| R_{low}(V_{applied}) | C_{low}(V_{applied})~0 | Z_{low}(V_{applied}) |

In an embodiment, Table 1 shows that a resistance of a variable impedance device, such as a device of embodiment 150, may transition between a lower resistance state, which, in an example embodiment, may comprise approximately zero (or negligible) resistance state, and a higher resistance that is a function, at least in part, of a voltage applied across such a device. Similarly, Table 1 shows that a capacitance of a variable impedance device, such as a device of embodiment 150, may transition between a lower capacitance state which, in an example embodiment, may comprise approximately zero (or negligible) capacitance, and a higher capacitance state that is a function, at least in part, of a voltage applied across such a device. Accordingly, a device of embodiment 150 may comprise a switching device capable of switching between and a low impedance and/or conductive state and a substantially dissimilar, high-impedance and/or insulative state as a function at least partially dependent on a voltage applied across such a device. In an embodiment, an impedance of a device of embodiment 150 exhibited at a low-impedance and/or conductive state may be approximately in the range of 10⁻¹ to 10⁻⁵ that of an impedance exhibited in a high-impedance and/or insulative state. In other embodiments, an impedance exhibited at a low-impedance and/or conductive state may be approximately in the range of 0.1 to 0.2 that of an impedance exhibited in a high-impedance and/or insulative state, for example. It should be noted, however, that claimed subject matter is not limited to any particular impedance ratios between high-impedance and/or insulative states and low-impedance and/or conductive states.

In certain embodiments, atomic layer deposition may be utilized to form and/or fabricate films comprising NiO materials, such as NiO:CO or NiO:NH₃. In this context, a “layer” as the term is used herein means a sheet and/or coating of material, which may be disposed on and/or over an underlying formation, such as a conductive or insulating substrate. For example, a layer deposited on an underlying substrate by way of an atomic layer deposition process may comprise a thickness dimension comparable to that of a single atom, which may comprise, for example, a fraction of an angstrom (e.g., 0.6 Å). However, in other embodiments, a layer may encompass a sheet and/or coating comprising a thickness dimension greater than that of a single atom depending, for example, on a process utilized to fabricate films comprising one or more CEM films. Additionally, a “layer” may be oriented horizontally (e.g., a “horizontal” layer), oriented vertically (e.g., a “vertical” layer), or may be positioned in any other orientation, such as diagonally, for example. In embodiments, a CEM film may comprise a sufficient number of layers, to permit electron back-donation during operation of a CEM device in a circuit environment, for example, to place such a CEM device in a low-impedance and/or conductive state. Also during operation in a circuit environment, for example, electron back-donation may be reversed so as to give rise to a substantially dissimilar impedance state, such as a high-impedance and/or insulative state, for example.

Also in this context, a “substrate” as used herein means a structure comprising a surface that enables materials, such as materials having particular electrical properties (e.g., conductive properties, insulative properties, etc.) to be deposited, formed and/or placed on and/or over the substrate. For example, in a CEM-based device, a conductive substrate may operate in a manner similar to first conductor 160 to conduct an electrical current to a CEM film in contact with conductive substrate 160. In another example, a substrate may operate to insulate a CEM film to prohibit electrical current flow to and/or from the CEM film. In one possible example of an insulating substrate, a material such as silicon nitride (SiN) may be employed to insulate components of semiconductor structures. Further, an insulating substrate may comprise other silicon-based materials such as silicon-on-insulator (SOI) or silicon-on-sapphire (SOS) technology, doped and/or undoped semiconductors, epitaxial layers of silicon supported by a base semiconductor foundation, conventional metal oxide semiconductors (CMOS), e.g., a CMOS front end with a metal back end, and/or other semiconductor structures and/or technologies, including CES devices, for example. Accordingly, claimed subject matter is intended to embrace a wide variety of conductive and insulating substrates without limitation.

In particular embodiments, formation of CEM films on and/or over a substrate may utilize two or more precursors to deposit components of, for example, NiO:CO or NiO:NH₃, other metal oxide or metal, or combination thereof, onto a conductive material such as a substrate. In an embodiment, layers of a CEM film may be deposited utilizing separate precursor molecules, AX and BY, according to expression (6A), below:

AX_{(gas)}+BY_{(gas)}=AB_{(solid)}+XY_{(gas)} (6A)

In an implementation, “A” of expression (6A) may correspond to a metal, metal compound or metal oxide, or any combination thereof, such as a transition metal, transition metal compound or transition metal oxide, or any combination thereof. In particular embodiments, such a transition metal, transition metal compound and/or transition metal oxide may comprise nickel, but may comprise other metals such as, for example, aluminum, cadmium, chromium, cobalt, copper, gold, iron, manganese, mercury, molybdenum, nickel palladium, rhenium, ruthenium, silver, tantalum, tin, titanium, vanadium, yttrium or zinc (which may be linked to an anion, such as oxygen or other types of ligands), or combinations thereof, although claimed subject matter is not limited in scope in this respect. In particular embodiments, compounds that comprise more than one transition metal oxide may also be utilized, such as yttrium titanate (YTiO₃).

In embodiments, “X” of expression (6A) may comprise a ligand, such as organic ligand, comprising amidinate (AMD), dicyclopentadienyl (Cp)₂, diethylcyclopentadienyl (EtCp)₂, Bis(2,2,6,6-tetramethylheptane-3,5-dionato) ((thd)₂), acetylacetonate (acac), bis(methylcyclopentadienyl) ((CH₃C₅H₄)₂), dimethylglyoximate (dmg)₂, 2-amino-pent-2-en-4-onato (apo)₂, (dmamb)₂ where dmamb=1-dimethylamino-2-methyl-2-butanolate, (dmamp)2 where dmamp=1-dimethylamino-2-methyl-2-propanolate, Bis(pentamethylcyclopentadienyl) (C₅(CH₃)₅)₂ or carbonyl (CO)₄. Accordingly, in some embodiments, nickel-based precursor AX may comprise, for example, nickel am idinate (Ni(AMD)), nickel dicyclopentadienyl (Ni(Cp)₂), nickel diethylcyclopentadienyl (Ni(EtCp)₂), Bis(2,2,6,6-tetramethylheptane-3,5-dionato)Ni(II) (Ni(thd)₂), nickel acetylacetonate (Ni(acac)₂), bis(methylcyclopentadienyl)nickel (Ni(CH₃C₅H4)₂, Nickel dimethylglyoximate (Ni(dmg)₂), nickel 2-amino-pent-2-en-4-onato (Ni(apo)₂), Ni(dmamb)₂ where dmamb=1-dimethylamino-2-methyl-2-butanolate, Ni(dmamp)₂ where dmamp=1-dimethylamino-2-methyl-2-propanolate, Bis(pentamethylcyclopentadienyl) nickel (Ni(C₅(CH₃)₅)₂ or nickel carbonyl (Ni(CO)₄), just to name a few examples.

In particular embodiments, layers of a metal oxide film may be formed by application of a dopant operating as an electron back-donating species in addition to precursors AX and BY. An electron back-donating species, which may co-flow with precursor AX, may permit formation of electron back-donating compounds, substantially in accordance with expression (6B), below. In embodiments, a dopant species and/or a precursor to a dopant species, such as carbonyl (CO)₄, ammonia (NH₃), methane (CH₄), carbon monoxide (CO), or other precursors and/or dopant species may be utilized to provide electron back-donating ligands listed above. Thus, expression (6A) may be modified to include an additional dopant ligand comprising an electron back-donating material substantially in accordance with expression (6B), below:

$${AX}_{( gas )} + ( {NH}_{3} or other ligand comprising nitrogen ) + {BY}_{( gas )} = AB \text{:} {NH}_{3 ( solid )} + {XY}_{( gas )} \qquad ( 6 B )$$

It should be noted that concentrations, such as atomic concentrations, of precursors, such as AX, BY, and NH₃ (or other ligand comprising nitrogen) of expressions (6A) and (6B) may be adjusted to give rise to a resulting atomic concentration of nitrogen-containing and/or carbon-containing dopant to permit electron back-donation in a fabricated CEM device. As referred to herein, the term “ligand atomic concentration” means a concentration of atoms in a finished material that derive from a substitutional ligand (e.g., from application of a dopant). For example, in the case in which a substitutional ligand comprises CO, an atomic concentration of CO in percentage terms comprises a total number of carbon atoms that comprise a material film divided by a total number of atoms in the material film, multiplied by 100.0. In another example, for a case in which a substitutional ligand is NH₃, an atomic concentration of NH₃ comprises a total number of nitrogen atoms that comprise a resulting material film divided by a total number of atoms in the resulting material film, multiplied by 100.0.

In particular embodiments, nitrogen- or carbon-containing dopants may comprise ammonia (NH₃), carbon monoxide (CO), or carbonyl (CO)₄ in an atomic concentration of between about 0.1% and about 20.0%. In particular embodiments, atomic concentrations of dopants, such as NH₃ and CO, may comprise a more limited range of atomic concentrations such as, for example, between about 1.0% and about 20.0%. However, claimed subject matter is not necessarily limited to the above-identified precursors and/or atomic concentrations. It should be noted that claimed subject matter is intended to embrace all such precursors and atomic concentrations of dopants utilized in atomic layer deposition, chemical vapor deposition, plasma chemical vapor deposition, sputter deposition, physical vapor deposition, hot wire chemical vapor deposition, laser enhanced chemical vapor deposition, laser enhanced atomic layer deposition, rapid thermal chemical vapor deposition, spin on deposition, gas cluster ion beam deposition, and/or the like, utilized in fabrication of CEM devices from metal oxide materials. In expressions (6A) and (6B), “BY” may comprise an oxidizer, such as water (H₂O), oxygen (O₂), ozone (O₃), plasma O₂, hydrogen peroxide (H₂O₂). In other embodiments, “BY” may comprise CO, O₂+(CH₄), nitric oxide (NO)+water (H₂O), an oxynitride, or carbon-containing gaseous oxidizing or oxynitridizing agent. In other embodiments, plasma may be used in combination with an oxidizer (BY) to form oxygen radicals (O*). Likewise, plasma may be used in combination with a dopant species to form an activated species to control dopant concentration in a CEM.

In particular embodiments, such as embodiments utilizing atomic layer deposition, a substrate, such as a conductive substrate, may be exposed to precursors, such as AX and BY of expression (6B), as well as dopants providing electron back-donation (such as ammonia or other ligands comprising metal-nitrogen bonds, including, for example, nickel-amides, nickel-imides, nickel-amidinates, or combinations thereof) in a heated chamber, which may attain, for example, a temperature of approximately in the range of 20.0° C. to 1000.0° C., for example, or between temperatures approximately in the range of 20.0° C. and 500.0° C. in certain embodiments. In one particular embodiment, in which atomic layer deposition of NiO:NH₃, for example, is performed, chamber temperature ranges approximately in the range of 20.0° C. and 400.0° C. may be utilized. Following exposure to precursor gases (e.g., AX, BY, NH₃, or other ligand comprising nitrogen), such gases may be purged from the heated chamber for durations approximately in the range of 0.5 seconds to 180.0 seconds, for example. It should be noted, however, that these are merely examples of potentially suitable ranges of chamber temperature and/or time and claimed subject matter is not limited in this respect.

In certain embodiments, a single two-precursor cycle (e.g., AX and BY, as described with reference to expression (6A)) or a single three-precursor cycle (e.g., AX, NH₃, CH₄, or other ligand comprising nitrogen, carbon, or other electron back-donating dopant to provide a substitutional ligand and BY, as described with reference to expression (6B)) utilizing atomic layer deposition may bring about a layer of a metal oxide material film comprising a thickness dimension approximately in the range of 0.6 Å to 5.0 Å per cycle. Accordingly, in one embodiment, if an atomic layer deposition process is capable of depositing layers of a metal oxide material film comprising a thickness dimension of approximately 0.6 Å, 800-900 two-precursor cycles may be utilized to bring about a metal oxide material film comprising a thickness dimension of approximately 500.0 Å. It should be noted that atomic layer deposition may be utilized to form metal oxide material films having other thickness dimensions, such as thickness dimensions approximately in the range of about 15.0 Å to about 1500.0 Å, for example, and claimed subject matter is not limited in this respect.

In particular embodiments, responsive to one or more two-precursor cycles (e.g., AX and BY), or three-precursor cycles (AX, NH₃, CH₄, or other ligand comprising nitrogen, carbon or other back-donating dopant material and BY), of atomic layer deposition, a metal oxide material film may be exposed to elevated temperatures, which may, at least in part, enable formation of a CEM device from a metal oxide material film. Exposure of the metal oxide material film to an elevated temperature may additionally enable activation of a back-donating dopant derived from a substitutional ligand, such as in the form of carbon monoxide, carbonyl, or ammonia, responsive to repositioning of the dopant to metal oxide lattice structures of the CEM device film.

Thus, in this context, an “elevated temperature” means a temperature at which substitutional or substitutional ligands evaporate from a metal oxide material film, and/or are repositioned within a metal oxide material film, to such an extent that the metal oxide material film transitions from a resistive film to a film that is capable of switching between a relatively high-impedance and/or insulative state to a relatively low-impedance and/or conductive state under operational conditions. For example, in certain embodiments, a metal oxide material film exposed to an elevated temperature within a chamber of about 100.0° C. to about 800.0° C. for a duration of about 1.0 seconds to about 10.0 minutes may permit evaporation of substitutional ligands from the metal oxide material film so as to form a CEM film. Additionally, in certain embodiments, a metal oxide material film exposed to an elevated temperature within a chamber of about 100.0° C. to about 800.0° C. for a duration of about 30.0 seconds to about 120.0 minutes may permit repositioning of substitutional ligands, for example, at oxygen vacancies within a lattice structure of a metal oxide. In particular embodiments, elevated temperatures and exposure durations may comprise more narrow ranges, such as, for example, temperatures of about 200.0° C. to about 500.0° C. for about 1.0 minute to about 60.0 minutes, for example, and claimed subject matter is not limited in these respects.

In particular embodiments, a CEM device manufactured in accordance with the above-described process may exhibit a “born on” property in which the device exhibits relatively low impedance (relatively high conductivity) immediately after fabrication of the device. Accordingly, if a CEM device is integrated into a larger electronics environment, for example, at initial activation a relatively small voltage applied to a CEM device may permit a relatively high current flow through the CEM device, as shown by region 104 of FIG. 1A. For example, as previously described herein, in at least one possible embodiment, a magnitude of Vᵣₑₛₑₜ may occur at a voltage approximately in the range of about 0.1 V to about 1.0 V, and a magnitude of Vₛₑₜ may occur at a voltage approximately in the range of about 1.0 V to about 2.0 V, for example. Accordingly, electrical switching voltages operating in a range of about 2.0 V, or less, may permit a memory circuit, for example, to change an impedance state of a CERAM device (e.g., to perform a “write operation” to a CERAM device) or detect an impedance state of a CERAM device (e.g., to perform a “read operation” on a CERAM device), for example. In embodiments, such relatively low voltage operation may reduce complexity, cost, and may provide other advantages over competing memory and/or switching device technologies.

In particular embodiments, two or more CEM devices may be formed within a particular layer of an integrated circuit at least in part by atomic layer deposition, chemical vapor deposition and/or physical vapor deposition of a material to be formed as CEM. In a further embodiment, one or more of a plurality of correlated electron switch devices of a first CEM and one or more of a plurality of correlated electron switch devices of a second CEM may be formed, at least in part, by a blanket deposition. Additionally, in an embodiment, first and second access devices may be positioned substantially adjacent to first and second CEM devices, respectively.

In a further embodiment, one or more of a plurality of CEM devices may be positioned within two or more levels of an integrated circuit at one or more intersections of electrically conductive metal layers of a first level and electrically conductive metal layers of a second level, which may be positioned over the first level of conductive metal layers. In this context a “metal layer” as the term is used herein, means a conductor capable of routing an electrical current from a first location to a second location of a layer of a multi-level CEM switching device. For example, a conductive metal layer may transport electrical current to or from an access device located at an intersection of a conductive metal layer of first level and a conductive metal layer of the second level. In certain embodiments, fabrication of a switching device formed from a multi-level CEM device, such as devices formed utilizing conductive metal layers positioned at multiple levels of a CEM switching device may be utilized in a CEM-based memory devices in which conductive metal layer positioned at multiple levels may facilitate an increase in bit line density, for example. Increases in bit line density may bring about more efficient and/or more highly integrated approaches toward controlling access to memory cells of CEM-based random access memory arrays, for example.

Also in this context, a “level” as the term is used herein, means a discrete surface, which a conductive metal layer may traverse, wherein such a discrete surface may be separated from other discrete surfaces immediately above and/or immediately below, by an insulating material. For example, as described herein, a conductive metal layer traversing a first level may be separated from a conductive metal layer traversing a second level by an insulating material, such as silicon nitride. In this context, a “multi-level” switching device, as the term is used herein, means a device to perform a switching function, such as from a high-impedance and/or insulative state to a low-impedance state, utilizing two or more of the above-described “levels.”

As described herein, in the course of deposition of one or more dopants on or over one or more layers of a first material, such as a transition metal, a transition metal oxide, a transition metal compound and/or transition metal alloy, an amount of an applied dopant may be accurately controlled so as to control an atomic concentration of a resulting ligand in CEM. Additionally, by depositing one or more dopant layers on or over one or more layers of a first material, localized regions of CEM may comprise differing atomic concentrations of dopants so as to provide an approach toward tailoring and/or customizing a dopant concentration profile. Further, dopant concentration profiles within a CEM may be increased via adjusting annealing temperatures and/or annealing durations. In addition to the above-identified advantages, particular embodiments may provide an approach toward fabricating and/or forming three-dimensional structures, such as 3D structures utilized for NAND flash memory. However, claimed subject matter is not limited to the above-identified advantages.

In particular implementations as described herein, annealing may be applied to deposited layers of a doped metal oxide to, for example, facilitate activation of bonding of a dopant with a metal oxide to provide one or more layers a CEM having desired switching characteristics. For example, a nickel oxide NiO may be doped with CO in a process to form layers of such a nickel oxide having desired switching characteristics. It should be understood, however, that use of annealing may be applicable to formation of a CEM from metal oxides other than nickel oxide and dopants other than CO (e.g., other carbon-based dopants such as carbonyl and/or nitrogen-based dopants such as NH₃), and claimed subject matter is not limited in this respect. Application of annealing to a layer of doped nickel oxide (e.g., prior to or after formation of a metal layer over the layers of the nickel oxide) may enable and/or facilitate a high concentration of Ni—CO—Ni having a desired switching behavior. However, application of heat over a long duration in a process to anneal metal oxide layers in formation of a CEM film may impart certain disadvantages such as production of such a CEM film with larger and/or non-uniform grain sizes over a wafer or over a device, undesirable effects to chemical composition of such a CEM film (particularly at a film surface) and/or undesirable impacts to a thermal budget in a process to form such a CEM film.

In a particular implementation, a period of annealing applied to a material (e.g., one or more layers forming a film) may be characterized, at least in part, by certain conditions (e.g., in a chamber) such as, for example, ambient temperature, chemical composition of ambient gas, pressure, temperature applied and a duration of time under which such a material is exposed to such conditions.

According to an embodiment, an anneal process may impart a temperature ramp of 10° C./sec at a surface of a device using technology such as a hot chuck. In particular embodiments for fabrication of devices to have particular switching behavior, durability or quality control, for example, such a temperature ramp may not be sufficient. As discussed below, other techniques may enable a rapid thermal anneal (RTA) in which a surface temperature of a device is increased at a higher rate (e.g., 100° C. per nanosecond (nsec)) by application of a heat source such as, for example, a laser source and/or a heat lamp. This may enable, among other things, improved process control and/or switching behavior of a CEM film formed from a doped metal oxide.

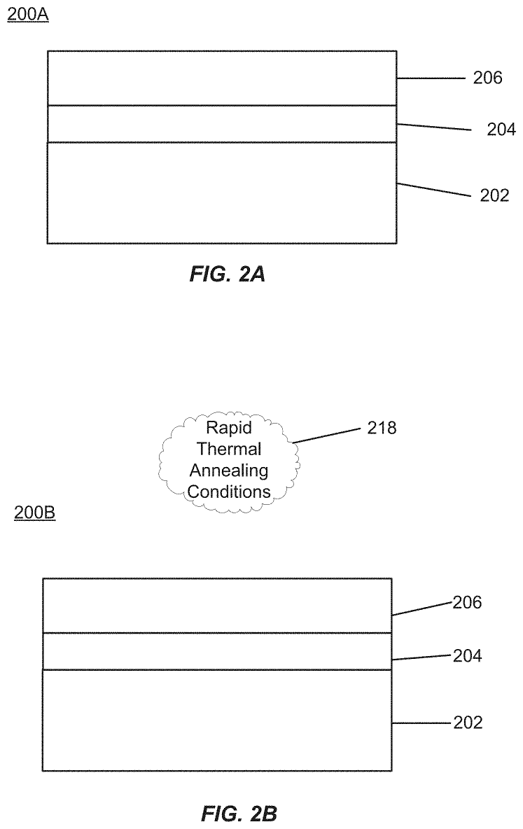

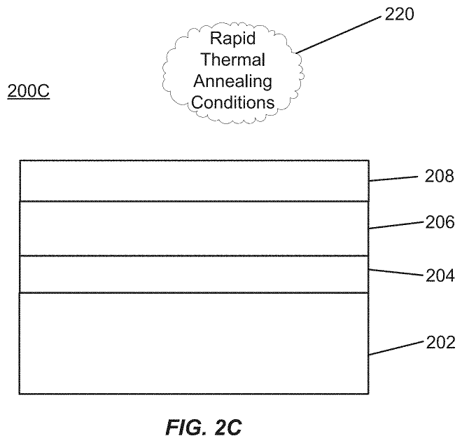

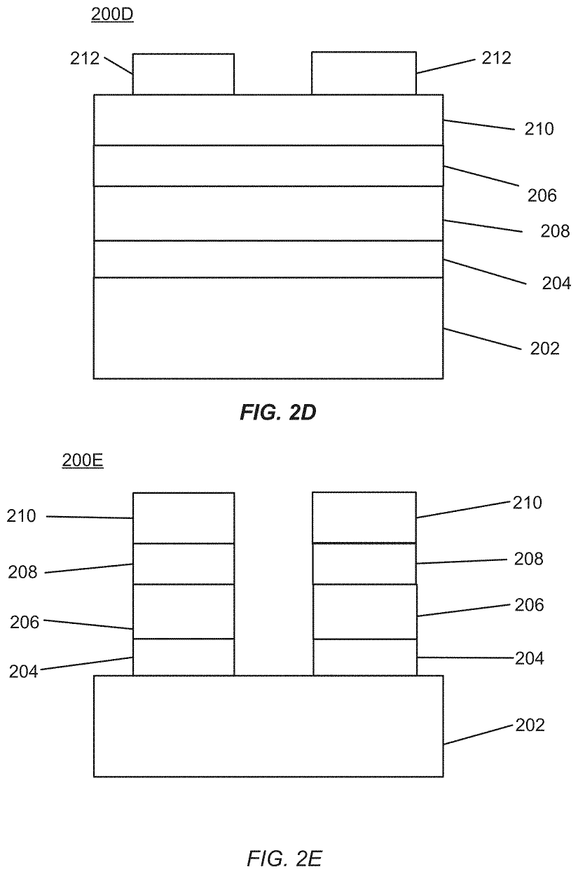

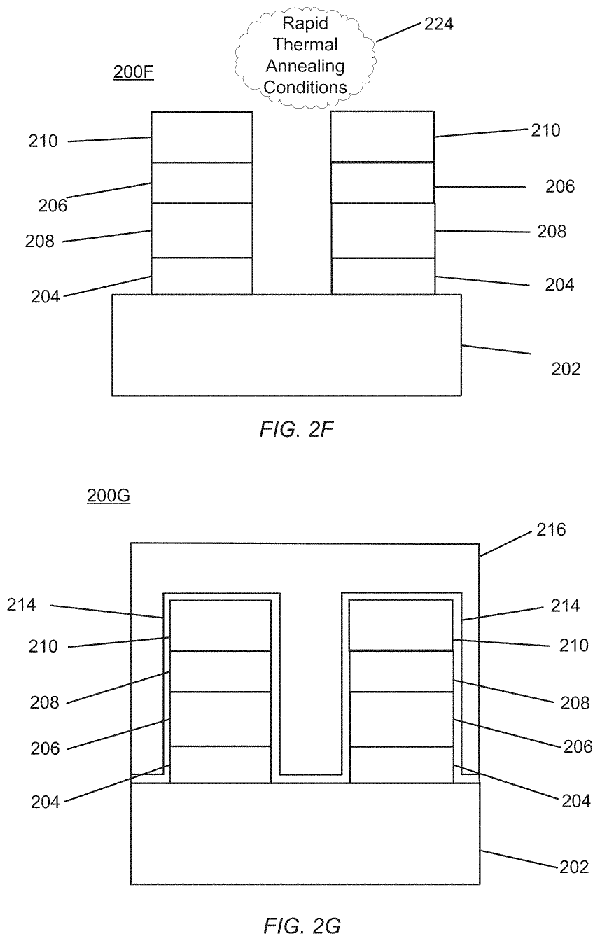

FIGS. 2A through 2G illustrate embodiments of sub-processes, which may be utilized in part to form a CEM device. In particular environments, sub-processes of FIGS. 2A through 2G may be performed during back-end-of-line integrated circuit fabrication processes (e.g., to form conducting structures following fabrication of transistor devices and/or other devices in a front-end-of-line integrated circuit fabrication), although in certain embodiments, aspects of one or more of the sub-processes illustrated in FIGS. 2A through 2G may be performed during other stages of a circuit fabrication process, and claimed subject matter is not limited in this respect. In particular implementations, a structure formed in subprocesses shown in FIGS. 2A through 2G may be exposed to rapid thermal annealing (RTA) conditions to, among other things, activate a dopant to form one or more layers of a CEM while reducing incidences of larger and/or non-uniform grain sizes over a wafer or over a device, reducing undesirable effects to (e.g., corruption of) chemical composition and/or reducing undesirable impacts to a thermal budget in a process to form such a CEM film. In an embodiment, activation of a dopant in a material comprising metal oxide using RTA may promote backdonation such that doped material exhibits p-type behavior, which may further enable desirable switching characteristics.

In particular implementations, first metal layer 204, second metal layer 208 and layers of metal oxide 206, hard mask layer 210, layer of SiN 214 and silicon oxide material 216 shown in FIGS. 2A through 2G may be formed using any one of several suitable deposition processes such as, for example, atomic layer deposition, chemical vapor deposition, plasma chemical vapor deposition, sputter deposition, physical vapor deposition, hot wire chemical vapor deposition, laser enhanced chemical vapor deposition, laser enhanced atomic layer deposition, rapid thermal chemical vapor deposition, spin on deposition, gas cluster ion beam deposition, and/or the like, utilized in fabrication of CEM devices from metal oxide materials. It should be noted, however, that first metal layer 204, second metal layer 208 and layers of metal oxide 206 and/or hard mask layer 210 may be formed utilizing other, different processes, and that claimed subject matter is not intended to be limited in this respect.

In the particular implementation of FIG. 2A, a first metal layer 204 may be formed over a substrate 202. In a particular implementation, substrate 202 may comprise transistors and/or lower metal interconnects (not shown) formed in a front end-of-line process such as any front end-of-line process to form complementary metal oxide semiconductor (CMOS) circuitry, just as an example. It should be understood, however that this is merely an example of how circuitry may be formed in a substrate in a front end-of-line process, and claimed subject matter is not limited in this respect.

According to an embodiment, first metal layer 204 may be formed over and/or on substrate 202. First metal layer 204 may comprise iridium, platinum, ruthenium, or rhodium, for example, having thicknesses of between about 1.0 nm and about 100.0 nm, for example. One or more layers of metal oxide 206 may be formed over and/or on first metal layer 204 and comprise NiO and/or other metal oxides such as, for example, HfOx, YOx, TiOx and/or TaOx, just to name a few. One or more layers of metal oxide 206 may also be doped with a carbon-containing dopant such as, for example, CO to a particular atomic concentration. In alternative implementations, one or more layers of metal oxide may be doped with other dopants such as NO (e.g., activated with an ambient O₂/N₂ gas mixture).

In an implementation, one or more layers of metal oxide 206, without further processing following deposition, may not have sufficient correlated electron switching characteristics (e.g., with sufficient amount of a ligand bonding with a metal oxide for backdonation to promote switching behavior) to enable desired switching behavior for a CEM device. For example, an insufficient amount of dopant (e.g., CO dopant) in layers of metal oxide 206 may bond with NiO to form Ni—CO—Ni with a density in bulk material to collapse band splitting, enabling a desired level of switching behavior. This may also be the case with application of dopants other than CO such as, for example, —CO where an insufficient amount of dopant may bond with NiO to form Ni—CO. As illustrated in FIG. 2B, according to an embodiment, rapid thermal annealing (RTA) conditions 218 may be applied to layers of metal oxide 206 (e.g., prior to formation of second metal layer 208 over layers of metal oxide 206).

In an embodiment, RTA conditions 218 may be applied while device 200 is disposed in a chamber (not shown) capable of controlling ambient process conditions such as, for example, pressure, temperature and gas chemistry. In an implementation, RTA conditions 218 may comprise maintaining a particular ambient gas chemistry to be predominantly CO₂, N₂ or O₂, or a combination thereof, and/or maintaining a particular pressure of approximately 10⁻⁶ atm. to 1.0 atm. It should be understood, however, that a different ambient gas chemistry may be maintained and that claimed subject matter is not limited in this respect. RTA conditions 218 may be further characterized, at least in part, by direct or indirect application of heat to layers of metal oxide 206 to significantly increase at least a surface temperature of layers of metal oxide 206 over a short time interval such as, for example, an increase in temperature by at least a threshold temperature difference (e.g., increase by degrees Kelvin or Celsius) over less than a set duration of time. This may be implemented, for example, by application of a laser scan over an exposed surface of metal oxide layers 206 (e.g., laser scan from a laser source over an exposed wafer surface).

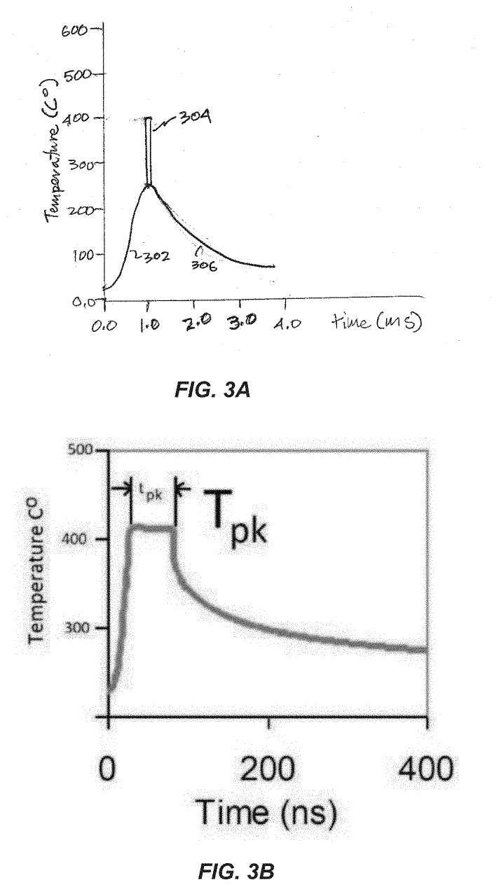

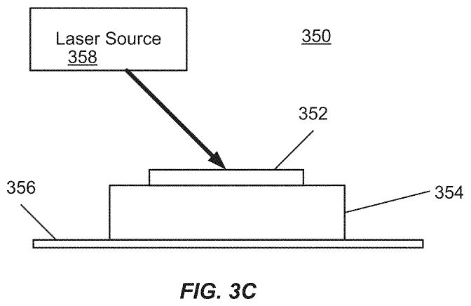

According to an embodiment, RTA conditions 218 may be applied, at least in part, according to aspects and/or features as shown in FIGS. 3A, 3B and 3C, for example. FIG. 3A is a plot of a surface temperature of a device (e.g., a surface temperature of a device comprising layers of metal oxide 206) including a preheating phase 302, followed by a rapid heating phase 304, and then followed by a cooling phase 306. In preheating phase 302, a surface temperature of a device may be increased at a rate of 100° C. to 400° C. per millisecond (ms), for example. Here, during rapid heating phase 304 a surface temperature of a device may be rapidly increased to a higher temperature, and maintained at the higher temperature for a predetermined duration, and then followed by a cooling phase (e.g., at a beginning of cooling phase 306). A surface temperature may cool in cooling phase 306 at a rate of about 100° C./ms. It should be understood, however, that these are merely example parameters which may in part specify a profile to be applied in an RTA process, and claimed subject matter is not limited in this respect.

FIG. 3B provides an exploded view of rapid heating phase 304 according to a particular embodiment. In a particular implementation, a surface temperature of a device may be increased by about 150° C. over a period of about 1.0 to 20 nsec, for example, to a peak temperature Tₚₖ. Peak temperature Tₚₖ in rapid heating phase 304 may be maintained at about 300° C. to 500° C. for a duration of 10-1000 ns. Parameters selected and controlled during rapid heating phase may be tailored for optimal activation of a dopant (e.g., carbon and/or nitrogen based dopant) in a metal oxide to promote back donation and switching behavior in a resulting CEM film. For example, techniques applying a rapid increase of device surface temperature to much higher temperatures (e.g., increase to temperatures of over 1000° C. for application to a semiconductor wafer to activate dopant affecting a material charge carrier concentration) may be incompatible with activation of a carbon-based and/or nitrogen-based dopant in a metal oxide to promote back donation and/or switching behavior. It should be understood, however, that these are merely example parameters which may in part specify a profile to be applied in an RTA process for activation of a dopant in a metal oxide to bring about back donation, and claimed subject matter is not limited in this respect.

FIG. 3C shows example features of an apparatus 350 to at least in part apply RTA conditions 218, 220 and/or 224 to a device. Device 352 (e.g., a device such as shown in FIG. 2B) may comprise a wafer and rest in contact with a chuck 354, which may further rest on a supporting substrate 356. In an embodiment, chuck 354 may at least in part serve as a heat sink to, among other things, assist in controlling a temperature of one or more portions of device 352 during one or more phases of an RTA process (e.g., preheating phase 302, rapid heating phase 304 and/or cooling phase 306). In a particular implementation, chuck 354 may be formed from a thermally conductive material (e.g., metal and/or metal alloy). Additionally, a temperature of chuck 354 may be controlled during phases of an RTA process to at least in part control a rate of sinking heat away from a surface of device 352 to thereby assist in controlling a temperature of device 352 in contact with chuck 354 (e.g., as measured by a temperature of a surface of device 352).

According to an embodiment, as pointed out above, a temperature of device 352 may be raised during an RTA process, at least in part, by application of laser energy to a surface of device 352. In a particular implementation, a laser source 358 may apply a laser scan over an exposed surface of device 352 (e.g., over a surface of layers 206) during a preheating phase (e.g., preheating phase 302) to raise a surface temperature of device 352 at a desired rate and to a desired preheat temperature. Here, laser source 358 may be powered to apply a first level of laser energy intensity to impinge on a surface of device 352 to, for example, at least in part raise and/or control a surface temperature an exposed surface of device 352 (e.g., during preheating phase 302). Laser source 358 may be then powered to a second, higher energy level to at least in part rapidly raise and/or control a surface temperature an exposed surface of device 352 (e.g., during rapid heating phase 304 to a desired temperature Tₚₖ). Alternatively, second laser source (not shown) may apply a laser scan over an exposed surface of device 352 (e.g., over a surface of layers 206) during a rapid heating phase (e.g., rapid heating phase 304) to raise a surface temperature of device 352 at a desired rate and to a desired temperature (e.g., raise a surface temperature of device 352 to a desired temperature Tₚₖ). In an alternative implementation, laser source 358 may be replaced with or combined with a heat lamp source (not shown) to raise and maintain a surface temperature of device 352 to a desired temperature Tₚₖ (e.g., rapid heating phase 304). According to an embodiment, apparatus 350 may further comprise one or more sensors (not shown) to measure temperature (e.g., directly or indirectly) at one or more locations of device 352 and/or a programmable computing device and/or processor devices (not shown) to determine control parameters for control signals so as to apply particular RTA conditions as illustrate in FIGS. 3A and 3B. Such control signals may be provided, for example, to laser source 358 and/or other heat sources (e.g., scan rate power level, etc.) and/or to control a flow of coolant to chuck 354 to control a rate of cooling.

In an alternative implementation, as illustrated in FIG. 2C, RTA annealing conditions 220 may be applied following formation of second metal layer 208 over layers of metal oxide 206. Here, second metal layer 208 may be formed to have substantially the same metal composition and thickness as first metal layer 204. According to an embodiment, RTA conditions 220 may comprise maintaining ambient conditions similar to that of RTA conditions 218 discussed above. RTA conditions 220 may further comprise application of a laser scan over an exposed surface of second metal layer 208 (e.g., laser scan over an exposed wafer surface).

According to an embodiment, application of RTA conditions 218 as shown in FIG. 2B prior to formation second metal layer 208 may enable removal of defects in layers of metal oxide 206. In an implementation, in addition to assisting in activation of a dopant in layers of metal oxide 206, application of RTA conditions 218 may assist in improved control information of poly crystals (e.g., assist in improving uniformity in poly crystal grain sizes). On the other hand, application of RTA conditions 220 as shown in FIG. 2C following formation of second metal layer 208 may assist in at least partially encapsulating layers of metal oxide 206 to at least partially prevent escape of a dopant during application of RTA (e.g., prevent escape of a carbon-based dopant and/or ligand as CO₂ gas). In an implementation, an interface between layers of metal oxide 206 and second metal layer 208 may be partially damaged in a process to form second metal layer 208 (e.g., through sputter deposition). Application of RTA 220 may assist in healing such an interface between layers of metal oxide 206 and second metal layer 208 by, for example, eliminating interface defect traps between second metal layer 208 and layers of metal oxide 206, to thereby improve CEM electrical performance.

As shown in FIG. 2D, hard mask layer 210 may be formed over second metal layer 208, and a photoresist layer 212 may be formed over hard mask layer 210 to cover portions of a top surface of hard mask layer 210 while leaving uncovered portions of top surface of hard mask layer 210 exposed. In an embodiment, hard mask 210 may comprise an oxide hard mask material such as a silicon dioxide, for example, although claimed subject matter is intended to embrace use of any hard mask material, virtually without limitation. Additionally, photoresist layer 212 may comprise any material suitable for use with a photolithographic process to form patterns in hard mask layer 210, for example. As shown in FIG. 2E, etching may be applied to exposed surfaces of hard mask layer 210 to remove exposed portions of hard mask layer 210, and to remove portions of first metal layer 204, layers of metal oxide 206 and second metal layer 208 beneath exposed surfaces of hard mask layer 210. Photoresist layer 212 may be patterned so as to expose portions of hard mask layer 210 to a physical or chemical etchant. Etching to provide structure 200E may comprise, for example, a dry etch process such as an ion beam etch, plasma sputter etch or other anisotropic etching process, or a combination thereof, which may occur in an etching chamber. As shown in FIG. 2F, according to an alternative embodiment, RTA conditions 224 may be applied following removal of portions of hard mask layer 210, and remove portions of first metal layer 204, layers of metal oxide 206 and second metal layer 208 beneath removed portions of hard mask layer 210 by etching. In an embodiment, RTA conditions 224 may be applied at least in part as shown in FIGS. 3A and 3B and as described above. In application of a heat source in an embodiment of RTA conditions 224, sidewalls of remaining portions of first metal layer 204, metal oxide layers 206, second metal layer 208 and hard mask layer 210, in addition to an top surface of remaining portions of hard mask 210 may be exposed to a rapidly elevated temperature (e.g., laser light may directly impinge exposed sidewalls). This may enable more efficient application of heat to portions of layers of metal oxide 206 to activate dopants for back donation, and form a sufficient density of pi bonds to achieve a desired switching behavior. Furthermore, in a process of etching to provide structure 200E, sidewalls of layers of metal oxide 206 may become damaged (e.g., losing back donation and/or switching properties). Application of RTA conditions 224 may, at least in part, assist in healing sidewalls of layers of metal oxide 206 damaged etching by, for example, at least partially restoring back donation and/or switching properties to damaged portions.

As shown in FIG. 2G, following etching to provide structure 200E (in FIG. 2E) and/or application of rapid thermal annealing conditions 224 to provide structure 200F (in FIG. 2F), structure 200E and/or structure 200F may be encapsulated by deposition of a layer of SiN or Al₂O₃ 214, followed by a filling by a with a silicon oxide material 216.

According to an embodiment, a host metal oxide material for use in forming layers of metal oxide 206 may comprise an abundance of interstitial anions MO₁₊ₓ and cation vacancies M₁₋ₓ NO brought about by oxidation, where “MO” represents a metal oxide (e.g., NiO). In an embodiment, a dopant may be applied to such a host metal oxide material to, for example, supply one or more ligands to bond with metal ions and fill cation vacancies M₁₋ₓO. In a particular implementation, a host metal oxide material may be doped with a carbon containing dopant, supplying a CO ligand to bond with metal ions thereby at least partially filling cation vacancies M₁₋ₓO in the host material. In an embodiment, a CO ligand to fill cation vacancies MO₁₋ₓ may form π-bonds to facilitate electron back donation (e.g., “π-backbonding”), enabling the host metal oxide material to behave more p-type. In a particular implementation, an amount of CO being supplied as a ligand to fill cation vacancies M₁₋ₓO may be controlled by, for example, controlling an amount of dopant applied to a host metal oxide material, thereby controlling a level of back donation occurring in available cation vacancies MO₁₋ₓ and a degree of p-type behavior.

According to an embodiment, rapid thermal annealing conditions 218, 220 and 224 as described above may, applied individually or collectively, enable freer diffusion of any vacancies, lower an activation energy for formation of CO bonds with metal (σ and/or π bonds), accelerate backdonation (e.g., from formation of π-bonds for CO to fill cation vacancies M₁₋ₓO) in metal oxide layers 206 (e.g., to increase and/or control p-type behavior in metal oxide layers 206) while mitigating effects of elevated temperatures applied for longer periods. Furthermore, shorter periods for application of heat to metal oxide layers 206 in rapid thermal annealing conditions 218, 220 and 224 may lower and/or reduce a thermal budget for transition of a doped metal oxide in an amorphous phase to a polycrystalline/semi-polycrystalline structure, limit or reduce Frenkel defects (e.g., ions on interstitial sites), and limit or reduce crystal grain size and/or improve crystal grain size uniformity (e.g., for nanoscale memory devices). As pointed out above, maintaining a peak surface temperature of about 300° C. to 500° C. in an RTA operation may enable formation of π bonds for backdonation while peak temperatures of over 1000° C., for example, may be incompatible for formation of π bonds.

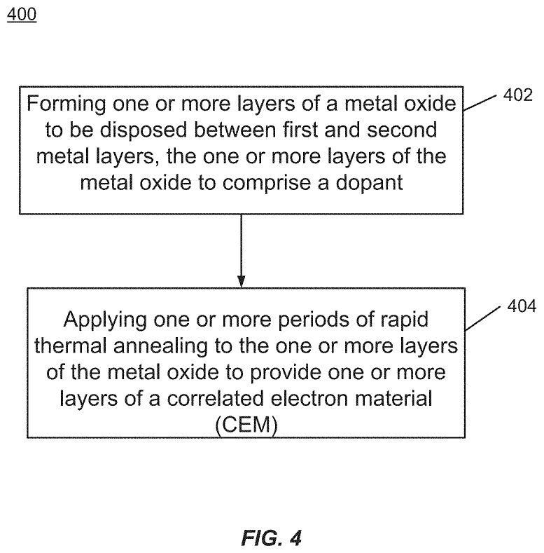

FIG. 4 is a flow diagram of a process 400 for forming a device according to an embodiment. Block 402 may comprise formation of one or more layers of a metal oxide to be disposed between first and second metal layers, such as formation of layers of metal oxide 206 between first and second metal layers 204 and 208. In a particular implementation, block 402 may form one or more layers to be disposed between first and second metal layers according to one or more aspects of a process characterized by expression (6A) and/or (6B), as an example. Block 404 may comprise application of one or more periods of RTA to the one or more layers of metal oxide formed in block 402 for formation of one or more layers of a CEM. For example, such one or periods of RTA may comprise application of RTA conditions 218 (e.g., prior to formation of second metal layer 208), 220 (e.g., following formation of second metal layer but prior to formation of hard mask layer 210) or 224 (following etching to expose sidewalls of layers of metal oxide 206), individually or in any combination.

According to an embodiment, “rapid thermal annealing conditions” as applied in block 404 means application of conditions to one or more layers of a metal oxide including raise a temperature of at least a portion of one or more layers of a doped metal oxide by at least 100° K. over a duration of no more than 1 sec. Such RTA conditions may be applied, at least in part, by applying laser scanning as shown in FIGS. 3A and 3B discussed above in a particular implementation.

In the preceding description, in a particular context of usage, such as a situation in which tangible components (and/or similarly, tangible materials) are being discussed, a distinction exists between being “on” and being “over.” As an example, deposition of a substance “on” a substrate refers to a deposition involving direct physical and tangible contact without an intermediary, such as an intermediary substance (e.g., an intermediary substance formed during an intervening process operation), between the substance deposited and the substrate in this latter example; nonetheless, deposition “over” a substrate, while understood to potentially include deposition “on” a substrate (since being “on” may also accurately be described as being “over”), is understood to include a situation in which one or more intermediaries, such as one or more intermediary substances, are present between the substance deposited and the substrate so that the substance deposited is not necessarily in direct physical and tangible contact with the substrate.

A similar distinction is made in an appropriate particular context of usage, such as in which tangible materials and/or tangible components are discussed, between being “beneath” and being “under.” While “beneath,” in such a particular context of usage, is intended to necessarily imply physical and tangible contact (similar to “on,” as just described), “under” potentially includes a situation in which there is direct physical and tangible contact but does not necessarily imply direct physical and tangible contact, such as if one or more intermediaries, such as one or more intermediary substances, are present. Thus, “on” is understood to mean “immediately over” and “beneath” is understood to mean “immediately under.”

It is likewise appreciated that terms such as “over” and “under” are understood in a similar manner as the terms “up,” “down,” “top,” “bottom,” and so on, previously mentioned. These terms may be used to facilitate discussion but are not intended to necessarily restrict scope of claimed subject matter. For example, the term “over,” as an example, is not meant to suggest that claim scope is limited to only situations in which an embodiment is right side up, such as in comparison with the embodiment being upside down, for example. An example includes a flip chip, as one illustration, in which, for example, orientation at various times (e.g., during fabrication) may not necessarily correspond to orientation of a final product. Thus, if an object, as an example, is within applicable claim scope in a particular orientation, such as upside down, as one example, likewise, it is intended that the latter also be interpreted to be included within applicable claim scope in another orientation, such as right side up, again, as an example, and vice-versa, even if applicable literal claim language has the potential to be interpreted otherwise. Of course, again, as always has been the case in the specification of a patent application, particular context of description and/or usage provides helpful guidance regarding reasonable inferences to be drawn.

Unless otherwise indicated, in the context of the present disclosure, the term “or” if used to associate a list, such as A, B, or C, is intended to mean A, B, and C, here used in the inclusive sense, as well as A, B, or C, here used in the exclusive sense. With this understanding, “and” is used in the inclusive sense and intended to mean A, B, and C; whereas “and/or” can be used in an abundance of caution to make clear that all of the foregoing meanings are intended, although such usage is not required. In addition, the term “one or more” and/or similar terms is used to describe any feature, structure, characteristic, and/or the like in the singular, “and/or” is also used to describe a plurality and/or some other combination of features, structures, characteristics, and/or the like. Furthermore, the terms “first,” “second,” “third,” and the like are used to distinguish different aspects, such as different components, as one example, rather than supplying a numerical limit or suggesting a particular order, unless expressly indicated otherwise. Likewise, the term “based on” and/or similar terms are understood as not necessarily intending to convey an exhaustive list of factors, but to allow for existence of additional factors not necessarily expressly described.

Furthermore, it is intended, for a situation that relates to implementation of claimed subject matter and is subject to testing, measurement, and/or specification regarding degree, to be understood in the following manner. As an example, in a given situation, assume a value of a physical property is to be measured. If alternatively reasonable approaches to testing, measurement, and/or specification regarding degree, at least with respect to the property, continuing with the example, is reasonably likely to occur to one of ordinary skill, at least for implementation purposes, claimed subject matter is intended to cover those alternatively reasonable approaches unless otherwise expressly indicated. As an example, if a plot of measurements over a region is produced and implementation of claimed subject matter refers to employing a measurement of slope over the region, but a variety of reasonable and alternative techniques to estimate the slope over that region exist, claimed subject matter is intended to cover those reasonable alternative techniques, even if those reasonable alternative techniques do not provide identical values, identical measurements or identical results, unless otherwise expressly indicated.

It is further noted that the terms “type” and/or “like,” if used, such as with a feature, structure, characteristic, and/or the like, using “optical” or “electrical” as simple examples, means at least partially of and/or relating to the feature, structure, characteristic, and/or the like in such a way that presence of minor variations, even variations that might otherwise not be considered fully consistent with the feature, structure, characteristic, and/or the like, do not in general prevent the feature, structure, characteristic, and/or the like from being of a “type” and/or being “like,” (such as being an “optical-type” or being “optical-like,” for example) if the minor variations are sufficiently minor so that the feature, structure, characteristic, and/or the like would still be considered to be predominantly present with such variations also present. Thus, continuing with this example, the terms optical-type and/or optical-like properties are necessarily intended to include optical properties. Likewise, the terms electrical-type and/or electrical-like properties, as another example, are necessarily intended to include electrical properties. It should be noted that the specification of the present disclosure merely provides one or more illustrative examples and claimed subject matter is intended to not be limited to one or more illustrative examples; however, again, as has always been the case with respect to the specification of a patent application, particular context of description and/or usage provides helpful guidance regarding reasonable inferences to be drawn.

In the preceding description, various aspects of claimed subject matter have been described. For purposes of explanation, specifics, such as amounts, systems, and/or configurations, as examples, were set forth. In other instances, well-known features were omitted and/or simplified so as not to obscure claimed subject matter. While certain features have been illustrated and/or described herein, many modifications, substitutions, changes, and/or equivalents will occur to those skilled in the art. It is, therefore, to be understood that the appended claims are intended to cover all modifications and/or changes as fall within claimed subject matter.

What is claimed is:

1. A method comprising:
forming one or more layers of a metal oxide to be disposed between first and second metal layers, the one or more layers of the metal oxide to comprise a dopant; and
applying one or more periods of rapid thermal annealing (RTA) to the one or more layers of the metal oxide to provide one or more layers of a correlated electron material (CEM).

2. The method of claim 1, and further comprising forming the second metal layer over the one or more layers of the metal oxide, wherein applying the one or more periods of rapid thermal anneal to comprise application of at least one of the one or more periods of rapid thermal anneal prior to the forming of the second layer over the one or more layers of the metal oxide.

3. The method of claim 2, wherein the application of the at least one of the one or more periods of rapid thermal anneal prior to the forming of the second layer over the one or more layers of the metal oxide to at least in part assist in imparting a backdonation property to the one or more layers of the metal oxide and control a grain size of a polycrystal formed in the one or more layers of the metal oxide.

4. The method of claim 1, and further comprising forming the second metal layer over the one or more layers of the metal oxide, wherein applying the one or more periods of rapid thermal anneal to occur subsequent to the forming of the second metal layer over the one or more layers of the metal oxide.

5. The method of claim 4, wherein the application of the at least one of the one or more periods of rapid thermal anneal subsequent to the forming of the second metal layer over the one or more layers of the metal oxide to at least in part assist in imparting a backdonation property to the one or more layers of the metal oxide and heal an interface between the one or more layers of the metal oxide and the second metal layer.

6. The method of claim 1, and further comprising etching at least a portion of the second metal layer and the one or more layers of the metal oxide, wherein applying of at least one of the one or more periods of rapid thermal anneal to occur subsequent to the etching of the at least a portion of the second metal layer and the one or more layers of the CEM.

7. The method of claim 6, wherein the application of the at least one of the one or more periods of rapid thermal anneal subsequent to the etching of the at least a portion of the second metal layer and the one or more layers of the CEM to at least in part restore a backdonation property to etched sidewalls of the one or more layers of the metal oxide.

8. The method of claim 1, wherein the metal oxide to comprise a nickel oxide and the CEM to comprise an atomic concentration of carbon of at least one part per million.

9. The method of claim 8, wherein application of the one or more periods of RTA to the one or more layers of the metal oxide to at least partially activate the carbon as a ligand to bond with metal oxide to thereby increase p-type behavior of the one or more layers of metal oxide.

10. The method of claim 1, wherein applying at least one of the one or more periods of rapid thermal annealing to the one or more layers of the metal oxide to comprise application of one or more laser sources or one or more heat lamp sources, or a combination thereof.

11. The method of claim 1, and further comprising disposing the one or more layers of the metal oxide over a chuck during at least a portion of at least one of the one or more periods of RTA, the chuck to sink heat from at least a portion of the one or more layers during the at least a portion of the at least one of the one or more periods of RTA.

12. The method of claim 1, wherein application of at least one of the one or more periods of RTA to comprise raising a temperature of at least one portion of the one or more layers of metal oxide by at least 100K over a period of no more than 1.0 sec.

13. The method of claim 1, wherein application of at least one of the one or more periods of RTA to comprise raising a temperature of at least one portion of the one or more layers of metal oxide to a peak temperature between 300°C. and 500° C. and maintaining the peak temperature for a duration of 10.0 to 1000.0 nanoseconds.

14. An apparatus comprising:
a substrate, the substrate to support a device comprising one or more layers of a metal oxide to be disposed over a first metal layer; and
one or more heat sources adapted to:
apply one or more periods of rapid thermal annealing (RTA) to the one or more layers of the metal oxide while disposed over the substrate to provide one or more layers of a correlated electron material (CEM).

15. The apparatus of claim 14, and further comprising a chuck disposed over the substrate, and wherein the chuck to be adapted to sink heat away from the device while the device is disposed on the chuck during at a portion of at least one of the one or more periods of RTA.

16. The apparatus of claim 14, wherein the device to comprise a first metal layer and a second metal layer, the one or more layers of the metal oxide to be disposed between the first metal layer and the second metal layer, and wherein the one or more laser sources to and further comprising forming the second metal layer over the one or more layers of the metal oxide, wherein applying the one or more periods of rapid thermal anneal to comprise application of at least one of the one or more periods of rapid thermal anneal prior to the forming of the second layer over the one or more layers of the metal oxide.

17. The apparatus of claim 14, wherein the device further to comprise a first metal layer, the one or more layers of the metal oxide to comprise a and further comprising forming the second metal layer over the one or more layers of the metal oxide, wherein applying the one or more periods of rapid thermal anneal to occur prior to the forming of the second layer over the one or more layers of the metal oxide.

18. The apparatus of claim 14, wherein application of at least one of the one or more periods of RTA to comprise an increase of a temperature of at least one portion of the one or more layers of metal oxide by at least 100K over a period of no more than 1 nec.

19. The apparatus of claim 14, wherein application of at least one of the one or more periods of RTA to comprise an increase of a temperature of at least one portion of the one or more layers of metal oxide to a peak temperature between 300° C. and 500° C., the peak temperature to be maintained for a duration of 10.0 to 1000.0 nanoseconds.

20. The apparatus of claim 14, wherein the one or more heat sources to comprise at least one laser source or at least one heat lamp source, or a combination thereof.

21. The apparatus of claim 14, and further comprising one or more processors to generate one or more signals to control power levels of at least one of the one or more heat sources during at least one of the one or more periods of RTA.
